(19) United States
(12) Patent Application Publication
(10) Pub. No.: US 2018/0159035 A1
(43) Pub. Date: Jun. 7, 2018

(54) EVAPORATION CARRIER PLATE AND EVAPORATION APPARATUS

(71) Applicant: BOE Technology Group Co., Ltd., Beijing (CN)

(72) Inventors: Ronggang Shangguan, Beijing (CN); Li Sun, Beijing (CN); Xinxin Wang, Beijing (CN); Kaihong Ma, Beijing (CN); Xiang Wan, Beijing (CN)

(21) Appl. No.: 15/575,077

(22) PCT Filed: Apr. 7, 2017
(86) PCT No.: PCT/CN2017/079745

§ 371 Date: Nov. 17, 2017

(30) Foreign Application Priority Data
Apr. 12, 2016 (CN) 201610225121.5

(51) Int. Cl. H01L 51/00; C23C 14/12; C23C 14/24; C23C 14/50; H01L 51/56

(52) U.S. Cl. CPC H01L 51/003; C23C 14/12; H01L 51/56; C23C 14/50; H01L 51/001; C23C 14/243

(57) ABSTRACT

An evaporation carrier plate and an evaporation apparatus are provided in embodiments of the disclosure, both belonging to the technical field of evaporation apparatus. The evaporation carrier plate comprises a carrier plate and a viscosity reducing portion which is provided on a first side surface of the carrier plate. An OLED substrate is secured on a second side surface opposite to the first side surface, of the carrier plate, by a sensitive adhesive, and the viscosity reducing portion is configured to operate so as to decrease viscosity of the sensitive adhesive following the evaporation.

### CROSS-REFERENCE TO RELATED INVENTION

This application is a Section 371 National Stage Application of International Application No. PCT/CN2017/079745, filed on 7 Apr. 2017, which has not yet published, and claims priority to Chinese Patent Application Invention No. 201610225121.5 filed on Apr. 12, 2016 in the State Intellectual Property Office of China, the disclosures of which are incorporated herein by reference.

### BACKGROUND OF THE DISCLOSURE

### Field of the Disclosure

Embodiments of the present disclosure relate to the technical field of evaporation apparatus, and in particular, to an evaporation carrier plate and an evaporation apparatus.

### Description of the Related Art

During a process of manufacturing an Organic Light Emitting Diode (abbreviated as OLED hereinafter), a crucible is used to evaporate an organic material for manufacturing the OLED onto the OLED substrate. Both the crucible and the OLED substrate are disposed within an evaporation chamber in a vacuum condition, and the OLED substrate is fixed above the crucible by an evaporation carrier plate.

Existing evaporation carrier plat comprises a carrier plate on which pin holes are provided. During evaporation, the OLED substrate is attached above all to a bottom surface of the carrier plate with viscous sucker glue, and then the carrier plate is transferred into the evaporation chamber by translation in an un-flipped condition; next, the crucible is used to evaporate the organic material for manufacturing the OLED onto the OLED substrate. Once the evaporation is completed, the carrier plate is flipped over such that a surface of the carrier plate on which the OLED substrate is provided is changed to face upwards. An operator operates a pin device such that ejector pins of the pin device penetrate through the pin holes of the carrier plate in a bottom-up manner so as to lift the OLED substrate by pushing thereon to facilitate separation of the evaporation carrier plate from the OLED substrate.

In processes of implementing embodiments of the disclosure, it has been found that there are at least some problems existing in the prior art, as below:

In the prior art, the OLED substrate is separated from the evaporation carrier plate by an external force applied by the ejector pins of the pin device. On one hand, especially at a position where the ejector pins lift the OLED substrate by pushing thereon, the OLED substrate is subject to an action of a relatively large local force and thus may readily undergo a deformation; while on the other hand, in case that the viscous sucker glue may exert a relatively strong adsorption force, the OLED substrate may not be easily separated from the evaporation carrier plate, i.e., a relatively larger external force is required; as a result, it may easily lead to a fact that the OLED substrate may be subject to an even larger local force so as to generate some fragments or debris which are peeled off the OLED substrate or to break the OLED substrate entirely, resulting in a disturbed or interrupted rhythm of production and a decreased product yield.

### SUMMARY OF THE DISCLOSURE

The embodiments of the present disclosure have been made to overcome or alleviate at least one aspect of the above mentioned disadvantages and/or shortcomings in the prior art, by providing an evaporation carrier plate and an evaporation apparatus.

Following technical solutions are adopted in exemplary embodiments of the invention for achieving the above desired technical purposes.

According to an aspect of the exemplary embodiment of the present disclosure, there is provided an evaporation carrier plate, comprising: a carrier plate; and a viscosity reducing portion, which is provided on a first side surface of the carrier plate; an OLED substrate is secured on a second side surface opposite to the first side surface, of the carrier plate, by a sensitive adhesive, and the viscosity reducing portion is configured to operate so as to decrease viscosity/sticky property of the sensitive adhesive following the evaporation.

According to an embodiment of the disclosure, the sensitive adhesive comprises one of a photo-sensitive adhesive and a heat-sensitive adhesive.

According to an embodiment of the disclosure, the sensitive adhesive is the heat-sensitive adhesive, and the viscosity reducing portion comprises a cooling pipe and a cryogenic fluid supply, the cooling pipe being provided on the carrier plate and positioned corresponding to a position on the carrier plate where the heat-sensitive adhesive is applied; the cryogenic fluid supply comprises a cryogenic fluid supply body, a first input port and a first output port, and the cooling pipe comprises a cooling pipe body, a second input port and a second output port; and the cryogenic fluid supply is configured to communicate with the second input port of the cooling pipe via the first output port thereof and to communicate with the second output port of the cooling pipe via the first input port thereof, following the evaporation; and is also configured to provide a cryogenic fluid to the cooling pipe.

According to an embodiment of the disclosure, the viscosity reducing portion further comprises a first check valve and a second check valve, the first check valve being provided between the first output port of the cryogenic fluid supply and the second input port of the cooling pipe and being configured to be switched on towards the second input port of the cooling pipe; while the second check valve being provided between the first input port of the cryogenic fluid supply and the second output port of the cooling pipe, and being configured to be switched on towards the first input port of the cryogenic fluid supply.

According to an embodiment of the disclosure, the viscosity reducing portion further comprises a first flow regulating valve provided between the first check valve and the second input port of the cooling pipe, and a second flow regulating valve provided between the second output port of the cooling pipe and the second check valve.

According to an embodiment of the disclosure, the carrier plate is provided with a cavity therein, in which the cooling pipe is in turn provided.

According to an embodiment of the disclosure, a groove is provided on the first side surface of the carrier plate facing away from the OLED substrate, and positioned to be aligned with a position on the carrier plate where the heat-sensitive adhesive is applied, with the cooling pipe being installed within the groove.

According to an embodiment of the disclosure, the cryogenic fluid is one of cooling water, cryogenic ethanol and liquid nitrogen.

According to an embodiment of the disclosure, the evaporation carrier plate further comprises pin holes formed thereon and a pin device having a plurality of ejector pins, and the pin device is configured to push upwards the OLED substrate to rise by the plurality of ejector pins which penetrate through the pin holes respectively so as to project therethrough to eject the OLED substrate in case that viscosity of the sensitive adhesive is decreased.

According to an embodiment of the disclosure, the pin device comprises: a pin mounting portion, which is mounted onto the carrier plate and configured to be movable in an axial direction of the pin holes; the plurality of ejector pins, each of which is fixed at one end thereof onto the pin mounting portion, and is inserted at the other end thereof into the pin holes respectively; and an automatic control portion, which is connected with the pin mounting portion; and the automatic control portion is configured to control the pin mounting portion to move in the axial direction of the pin holes in case that viscosity of the sensitive adhesive is decreased, such that each of the plurality of ejector pins penetrates through the pin holes respectively to project therethrough so as to push upwards the OLED substrate to rise.

According to an embodiment of the disclosure, each of the plurality of ejector pins are provided with a first deep hole and a second deep hole in an axial direction thereof in communication with the first deep hole, both of which are in communication with the cryogenic fluid supply respectively.

According to an embodiment of the disclosure, a cross section of a position where the first deep hole and the second deep hole of each of the plurality of ejector pins communicate with each other is larger than a cross section of either one of the first deep hole and the second deep hole.

According to an embodiment of the disclosure, the cooling pipe is secured to the carrier plate by one of welding or snap-fit.

According to an embodiment of the disclosure, a material of the cooling pipe comprises one of copper, silver, aluminum, molybdenum and tungsten.

According to an embodiment of the disclosure, the sensitive adhesive is the photo-sensitive adhesive, and the viscosity reducing portion comprises a viscosity reducing light source and a light mask plate, the carrier plate is provided therein with a mounting chamber for the viscosity reducing light source in which the viscosity reducing light source is in turn mounted, a position on the carrier plate where the photo-sensitive adhesive is applied being within a range of illumination by the viscosity reducing light source, and the light mask plate is provided on the second side surface of the carrier plate facing towards the OLED substrate, and is configured to shield a location on the OLED substrate which is covered with an organic material for manufacturing the OLED by the evaporation but without the photo-sensitive adhesive being applied thereon.

According to an embodiment of the disclosure, the viscosity reducing light source is an ultraviolet light source.

According to an aspect of the exemplary embodiment of the present disclosure, there is provided an evaporation apparatus, comprising the evaporation carrier plate as above.

### BRIEF DESCRIPTION OF THE DRAWINGS

The above and other features and advantages of the present disclosure will become more apparent and a more comprehensive understanding of the present disclosure can be obtained, by describing in detail exemplary embodiments thereof with reference to the accompanying drawings, in which:

FIG. 1 illustrates a structural schematic perspective view of an evaporation carrier plate according to an embodiment of the disclosure, as well as an OLED substrate;

FIG. 2 illustrates a schematic view of the evaporation carrier plate in an operation condition thereof according to another embodiment of the disclosure;

FIG. 3 illustrates a structural schematic top view of the evaporation carrier plate according to another embodiment of the disclosure;

FIG. 4 illustrates a structural schematic perspective view of a carrier plate according to another embodiment of the disclosure;

FIG. 5 illustrates a structural schematic perspective view of the evaporation carrier plate according to another embodiment of the disclosure, as well as the OLED substrate;

FIG. 6 illustrates a schematic view of the evaporation carrier plate in a condition in which the OLED substrate is lifted by ejector pins pushing thereon, according to another embodiment of the disclosure;

FIG. 7 illustrates a structural schematic view of the ejector pins according to another embodiment of the disclosure;

FIG. 8 illustrates a structural schematic perspective view of a carrier plate and a viscosity reducing light source according to yet another embodiment of the disclosure;

FIG. 9 illustrates a structural schematic perspective view of the carrier plate and a light mask plate according to yet another embodiment of the disclosure.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms, and thus the detailed description of the embodiment of the disclosure in view of attached drawings should not be construed as being limited to the embodiment set forth herein; rather, these embodiments are provided so that the present disclosure will be thorough and complete, and will fully convey the general concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Respective dimension and shape of each component in the drawings are only intended to exemplarily illustrate the contents of the disclosure, rather than to demonstrate the practical dimension or proportion of components of the evaporation carrier plate and the evaporation apparatus.

As illustrated in FIG. 1, according to a general technical concept of the present disclosure, there is provided an evaporation carrier plate, comprising: a carrier plate 1; and a viscosity reducing portion 2, which is provided on a first side surface of the carrier plate 1, e.g., an upper surface as in the condition as shown in FIG. 1. An OLED substrate 3 is secured on a second side surface opposite to the first side surface, of the carrier plate 1, by a sensitive adhesive 4, and the viscosity reducing portion 2 is configured to operate so as to decrease viscosity/stickiness of the sensitive adhesive 4 following the evaporation.

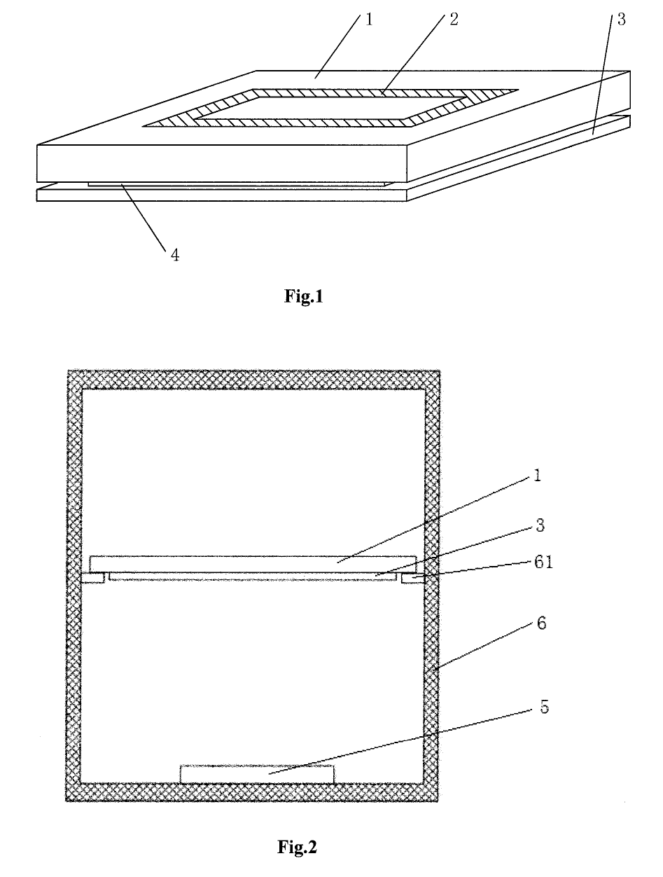

As illustrated in FIG. 2, and in view of FIG. 1, in an embodiment of the disclosure, the viscosity reducing portion 2 is formed in advance on the first side surface of the carrier plate 1. Once an organic material is required to be evaporated on the OLED substrate 3, the OLED substrate 3 is fixed onto the second side surface of the evaporation carrier plate, opposite to the first side surface, by the sensitive adhesive 4, and then the evaporation carrier plate is transferred into a vacuum evaporation chamber 6 by translation in an un-flipped condition, such that the OLED substrate 3 is attached below the evaporation carrier plate, with a side thereof which is to be evaporated facing downwards. Furthermore, an evaporation crucible is provided within the vacuum evaporation chamber 6, and located immediately below the OLED substrate 3. The evaporation carrier plate is restricted in place, e.g., by steps 61 on side walls of the vacuum evaporation chamber 6, or is fixed inside the vacuum evaporation chamber 6 by a screw or screws, and the like.

Once the evaporation is completed, the evaporation carrier plate is transferred from the vacuum evaporation chamber 6 into a separation chamber; and then is flipped over in the separation chamber such that the second side surface on which the OLED substrate 3 is provided is changed to face upwards, and thus the OLED substrate 3 is located above the evaporation carrier plate with the evaporated side thereof facing upwards. At the time, viscosity of the sensitive adhesive 4 is reduced by the viscosity reducing portion 2 provided on the first side surface of the carrier plate 1, facilitating separation of the OLED substrate 3 from the carrier plate 1 once the sensitive adhesive 4 loses its viscosity/stickiness or has a weakened viscosity/stickiness insufficient to maintain the bonding fixation between the OLED substrate 3 and the carrier plate 1, so as to remove the OLED substrate 3 from the carrier plate 1.

In exemplary embodiments of the disclosure, the viscosity/stickiness of the sensitive adhesive 4 is decreased by the viscosity reducing portion 2 after evaporation, facilitating separation between the OLED substrate 3 and the evaporation carrier plate, so as to avoid an occurrence of deformation of the OLED substrate, or generation of fragments or debris from the OLED substrate, or even an overall breakup thereof, and in turn to avoid any adverse effect on both rhythm of production and product yield, when the evaporation carrier plate is separated from the OLED substrate 3 only by an external force.

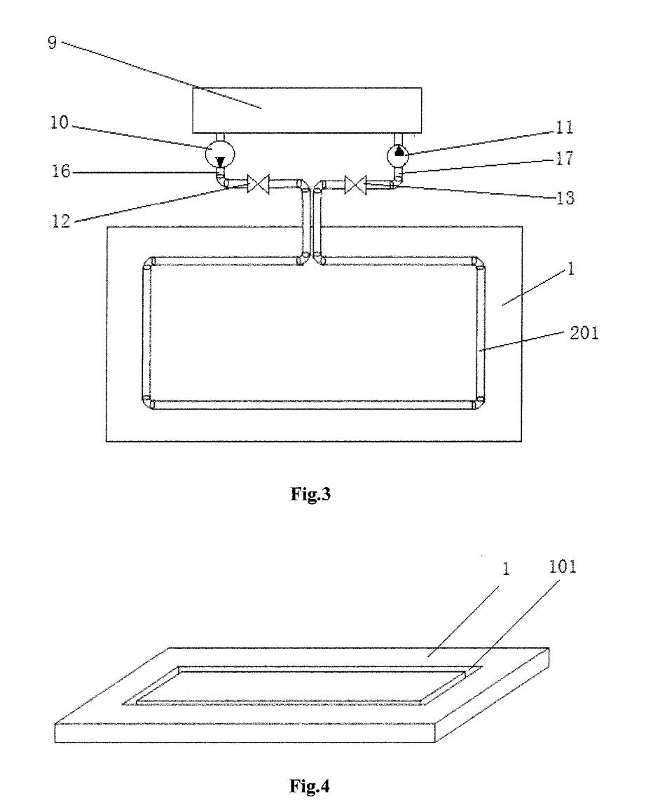

In an embodiment of the disclosure, as illustrated in FIG. 3, by way of example, the sensitive adhesive 4 is the heat-sensitive adhesive, and the viscosity reducing portion 2 comprises a cooling pipe 201 and a cryogenic fluid supply 9, the cooling pipe 201 being provided on the carrier plate 1 and positioned corresponding to and in coincidence with a position on the carrier plate where the heat-sensitive adhesive is applied, e.g., in a vertical alignment; the cryogenic fluid supply comprises a cryogenic fluid supply body, a first input port and a first output port, and the cooling pipe comprises a cooling pipe body, a second input port and a second output port.

After the evaporation is completed, the cryogenic fluid supply 9 communicates with the second input port of the cooling pipe 201 via the first output port thereof and communicates with the second output port of the cooling pipe 201 via the first input port thereof, so as to form a circuit in which the cryogenic fluid circulates; and the cryogenic fluid supply is also configured to provide a cryogenic fluid to the cooling pipe 201.

In an embodiment of the disclosure, a circle of the heat-sensitive adhesive is applied at a middle portion of the second side surface of the carrier plate 1 so as to secure the OLED substrate 3 onto the carrier plate 1. The viscosity/stickiness of the heat-sensitive adhesive at a temperature which is equal to or over a room temperature or an ambient temperature is larger than that at temperature below the room temperature or the ambient temperature, especially below zero degrees Celsius. In the embodiments of the disclosure, since the temperature inside the vacuum evaporation chamber 6 during the evaporation is higher than the room temperature or the ambient temperature, then once the carrier plate 1 is placed within the vacuum evaporation chamber 6 the viscosity of the heat-sensitive adhesive is correspondingly stronger than that at the room temperature or the ambient temperature, such that the OLED substrate 3 is fixedly secured onto the carrier plate 1 by the heat-sensitive adhesive. Once the evaporation is completed, as illustrated in FIG. 3, the heat-sensitive adhesive is cooled so as to decrease its temperature by the cryogenic fluid circulating inside the circuit of the viscosity reducing portion 2, such that the viscosity thereof is decreased so as to facilitate separation between the OLED substrate 3 and the carrier plate 1.

The cooling pipe 201 is secured onto the carrier plate 1, for example, by welding or by snap-fit. The cryogenic fluid supply 9 is for example provided within the separation chamber; or alternatively, it is placed outside the separation chamber, e.g., in heat exchange with an external refrigeration device or an external heat dissipator. During the evaporation, the cryogenic fluid supply 9 is separated from the cooling pipe 201 and disconnected therewith; while once the evaporation is completed, the carrier plate 1 is transferred into the separation chamber and then the cryogenic fluid supply 9 is connected with the cooling pipe 201 such that the cryogenic fluid supply 9 provides the cooling pipe 201 with the cryogenic fluid and the cryogenic fluid circulates in the circuit between the cooling pipe 201 and the cryogenic fluid supply 9. Then, during the circulation flow of the cryogenic fluid, by a heat exchange between the cooling pipe 201 and the carrier plate 1, there will in turn be another heat exchange between the heat-sensitive adhesive and the carrier plate 1, so as to decrease the temperature of the heat-sensitive adhesive and in turn the viscosity thereof.

In an embodiment of the disclosure, for example, a material of the cooling pipe 201 comprises copper, silver, aluminum, molybdenum or tungsten, and a material of the carrier plate 1 may also comprise copper, silver, aluminum, molybdenum, tungsten or an aluminum alloy. Therefore, both the cooling pipe and the carrier plate are provided with a superior heat conductivity which facilitates exchange between the cryogenic fluid and the carrier plate 1.

As illustrated in FIG. 3, in an embodiment of the disclosure, by way of example, the viscosity reducing portion 2 further comprises a first check valve 10 and a second check valve 11, the first check valve 10 being provided between the first output port of the cryogenic fluid supply 9 and the second input port of the cooling pipe 201; while the second check valve 11 being provided between the first input port of the cryogenic fluid supply 9 and the second output port of the cooling pipe 201.

In an embodiment of the disclosure, for example, the second input port of the cooling pipe 201 communicates with the first output port of the cryogenic fluid supply 9 via an input pipe 16, and the first check valve 10 is provided on the input pipe 16 and configured to be switched on towards the second input port of the cooling pipe 201; and the second output port of the cooling pipe 201 communicates with the first input port of the cryogenic fluid supply 9 via an output pipe 17, and the second check valve 11 is provided on the output pipe 17 and configured to be switched on towards the first input port of the cryogenic fluid supply 9. As such, an unidirectional circulation flow of the cryogenic fluid between the cryogenic fluid supply 9 and the cooling pipe 201 is ensured by the first check valve 10 and the second check valve 11, such that it may be ensured that the cryogenic fluid which is delivered from the cryogenic fluid supply 9 into the cooling pipe 201 may be maintained at a relatively low temperature.

As illustrated in FIG. 3, in an embodiment of the disclosure, for example, the viscosity reducing portion 2 further comprises a first flow regulating valve 12 provided between the first check valve 10 and the second input port of the cooling pipe 201, and a second flow regulating valve 13 provided between the second output port of the cooling pipe 201 and the second check valve 11.

In an embodiment of the disclosure, the first flow regulating valve 12 is provided on the input pipe 16, and located between the first check valve 10 and the cooling pipe 201, and the second flow regulating valve 13 is provided on the output pipe 17 and located between the second check valve 11 and the cooling pipe 201. Since the viscosity of the heat-sensitive adhesive is closely related to the temperature thereof and may be minimized when the temperature decreases below a certain temperature, then, by regulating the flow of the cryogenic fluid within the cooling pipe 201 by the first flow regulating valve 12 and the second flow regulating valve 13, a cooling temperature as required may be calculated so as to facilitate control of the temperature of the heat-sensitive adhesive, and in turn to ensure that the OLED substrate 3 and the carrier plate 1 are separated from each other once the viscosity of the heat-sensitive adhesive is minimized.

As illustrated in FIG. 4, in an embodiment of the disclosure, for example, a groove 101 is provided on the first side surface of the carrier plate 1 facing away from the OLED substrate 3, and positioned corresponding to a position on the carrier plate 1 where the heat-sensitive adhesive is applied, with the cooling pipe 201 being installed within the groove 101.

In an embodiment of the disclosure, by mounting the cooling pipe 201 within the groove 101, a contact area between the cooling pipe 201 and the carrier plate 1 is increased so as to facilitate a sufficient heat exchange therebetween. For example, the groove 101 is in a form of a circular arc shape, e.g., an inner wall of the groove is in a form of a partially cylinder inner wall whose internal diameter is constant and equal to an external diameter of the cooling pipe, such that the cooling pipe 201 is installed within the groove 101 and arranged to abut against the inner wall of the groove 101, so as to further increase the contact area between the cooling pipe 201 and the carrier plate 1.

In an embodiment of the disclosure, further for example, the carrier plate 1 is provided therein with a cavity spaced apart from the separation chamber, in which cavity the cooling pipe 201 is in turn provided, such that an outer wall of the cooling pipe 201 abuts closely against an inner surface of the cavity.

By providing the cooling pipe 201 within the cavity inside the carrier plate 1 which is spaced apart from the separation chamber, an exchange between the cooling pipe 201 and air within the separation chamber may be avoided so as to decrease heat loss and to enhance a refrigeration efficiency of the cryogenic fluid within the cooling pipe 201.

In an embodiment of the disclosure, for example, the cryogenic fluid is cooling water, a cryogenic ethanol or liquid nitrogen, or the like, and may specifically be selected therefrom depending on the temperature as required in case that the viscosity of the heat-sensitive adhesive is minimized. By way of example, cooling water may be selected as the cryogenic fluid if the temperature which is required to minimize the viscosity of the heat-sensitive adhesive is in a range of 0˜10 degrees Celsius.

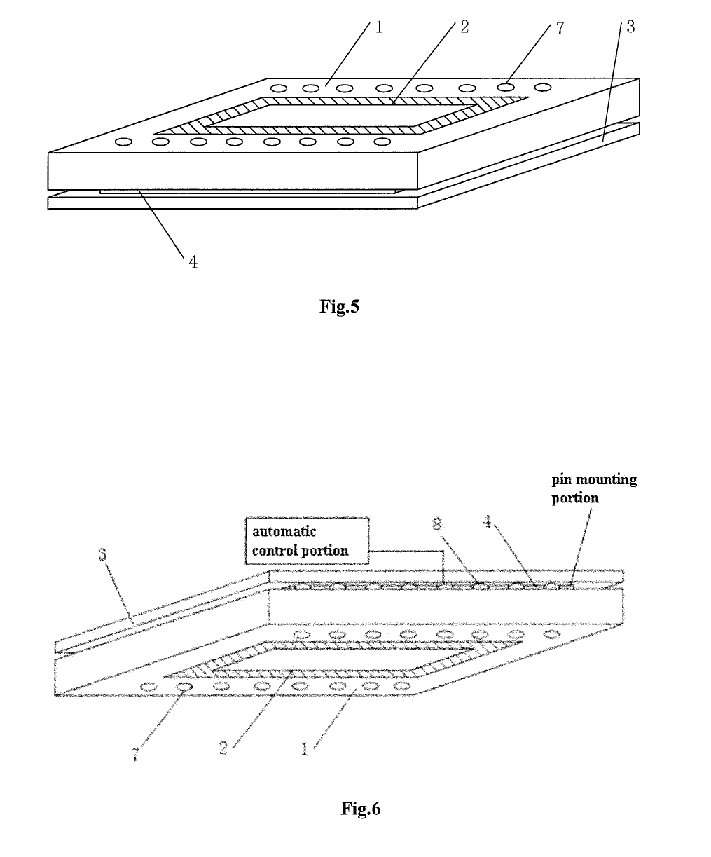

In an embodiment of the disclosure, for example, the evaporation carrier plate may optionally comprise a pin device, and as illustrated in FIG. 6, the pin device is provided with a plurality of ejector pins 8 thereon. As illustrated in FIG. 5, pin holes 7 are formed on the carrier plate 1, and the pin device may push upwards the OLED substrate 3 to rise by the plurality of ejector pins 8 which penetrate through the pin holes 7 respectively so as to project therethrough to eject the OLED substrate 3 once viscosity of the sensitive adhesive 4 is decreased.

In an embodiment of the disclosure, once the viscosity of the sensitive adhesive 4 is decreased, the OLED substrate 3 still remains attached/bonded onto the carrier plate 1. As such, in order to facilitate pickup of the OLED substrate 3 by a robot arm extending to reach between the OLED substrate 3 and the carrier plate 1, the OLED substrate 3 is lifted by the pin device so as to create a gap between the OLED substrate 3 and the carrier plate 1 which gap is sized sufficiently to enable pickup of the OLED substrate by the robot arm inserting therebetween, so as to adapt to a tendency of automatic production.

Referring to FIG. 6, in an embodiment of the disclosure, specifically, by way of example, the pin device comprises: a pin mounting portion, the plurality of ejector pins 8 and an automatic control portion. The pin mounting portion is for example mounted onto the carrier plate 1 and configured to be movable in an axial direction of the pin holes 7. Moreover, for example, each of the plurality of ejector pins 8 is fixed at one end thereof onto the pin mounting portion, and is inserted at the other end thereof into the pin holes 7 respectively; and the automatic control portion is connected with the pin mounting portion so as to instruct a movement of the pin mounting portion. And the automatic control portion is configured to control the pin mounting portion to move in the axial direction of the pin holes 7 once viscosity of the sensitive adhesive is decreased. As such, as illustrated in FIG. 6, each of the plurality of ejector pins 8 penetrates through the pin holes 7 respectively to project therethrough so as to push upwards the OLED substrate 3 to rise.

In an example of the disclosure, the pin mounting portion and the carrier plate 1 may for example be provided individually; or the carrier plate 1 is provided therein with a pocket in which the pin mounting portion is provided and the pin mounting portion may in turn move in the axial direction of the pin holes 7 so as to drive the plurality of ejector pins 8 in motion within the pin holes 7 respectively. The OLED substrate 3 may be lifted up by the automatic control portion which controls the pin mounting portion to move in the axial direction of the pin holes 7, without any manual operation, so as to adapt to a tendency of automatic production. In an embodiment of the disclosure, a number of the plurality of ejector pins 8 is at least two, and the plurality of ejector pins 8 are arranged at least on a pair of opposite sides of a quadrilateral, respectively.

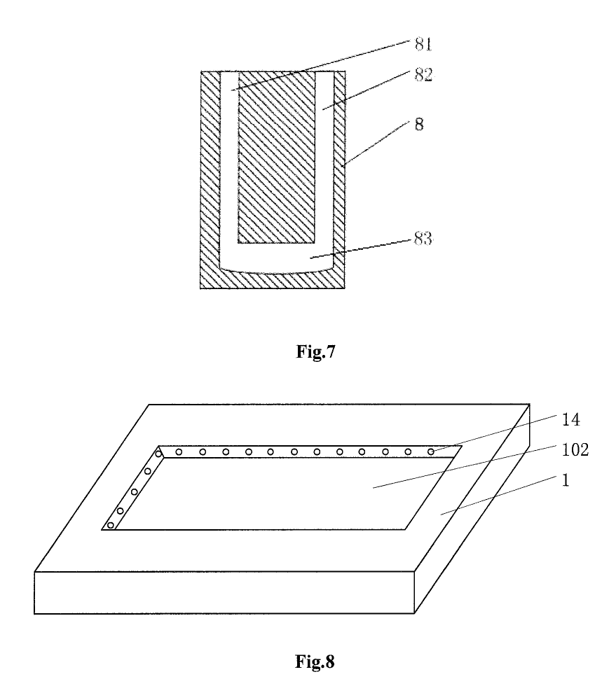

As illustrated in FIG. 7, in an embodiment of the disclosure, each of the plurality of ejector pins 8 is provided with a first deep hole 81 and a second deep hole 82 in an axial direction thereof in communication with the first deep hole 81, both of which are in communication with the cryogenic fluid supply 9 respectively.

By a circulation channel of the cryogenic fluid which is formed by the communication between the cryogenic fluid supply 9 and both the first deep hole 81 and the second deep hole 82, cooling of the heat-sensitive adhesive is assisted so as to enhance a cooling efficiency. Certainly, it may be known to those skilled in the art that, when there are a large number of the plurality of ejector pins 8 which are all arranged adjacent to the heat-sensitive adhesive, the heat-sensitive adhesive may for example be cooled so as to lower its temperature directly by the circulation channel formed between the cryogenic fluid supply 9 and both the first deep hole 81 and the second deep hole 82, without the cooling pipe 201, resulting in a decreased cost of production.

As illustrated in FIG. 7, by way of example, in an embodiment of the disclosure, a cross section of a position where the first deep hole 81 and the second deep hole 82 of each of the plurality of ejector pins 8 communicate with each other is larger than a cross section of either one of the first deep hole 81 and the second deep hole 82.

In an embodiment of the disclosure, at a side of each of the plurality of ejector pins 8 adjacent to the OLED substrate 3, the first deep hole 81 and the second deep hole 82 thereof communicate with each other so as to form a cooling head 83 which has a larger cross section area than that of either the first deep hole 81 or the second deep hole 82, such that there is a sufficient heat exchange between the cryogenic fluid in the cooling head 83 and the heat-sensitive adhesive to ensure the refrigeration efficiency of the cryogenic fluid.

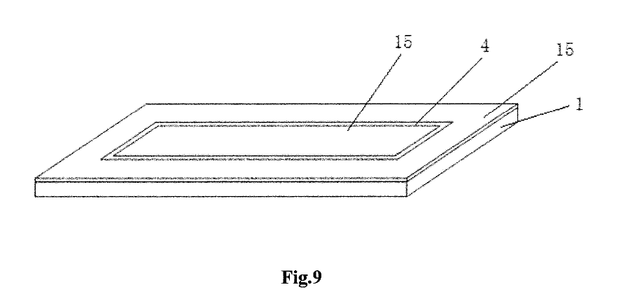

In another embodiment of the disclosure, as illustrated in FIG. 8 and referring to FIG. 9, the sensitive adhesive 4 is the photo-sensitive adhesive, and the viscosity reducing portion 2 comprises a viscosity reducing light source 14 and a light mask plate 15. And the carrier plate 1 is provided therein with a mounting chamber 102 for the viscosity reducing light source in which the viscosity reducing light source 14 is in turn mounted, a position on the carrier plate 1 where the photo-sensitive adhesive is applied being within a range of illumination by the viscosity reducing light source 14. Moreover, the light mask plate 15 is provided on the second side surface of the carrier plate 1 facing towards the OLED substrate 3, and is configured to shield a location on the OLED substrate 3 which is covered with an organic material for manufacturing the OLED by the evaporation but without the photo-sensitive adhesive being applied thereon.

In this embodiment, the photo-sensitive adhesive has a larger viscosity/stickiness once illuminated by a normal light source, facilitating a fixed attachment of the OLED substrate 3 onto the evaporation carrier plate. Once the evaporation is completed, by applying an illumination by a special light source, such as an ultraviolet light source and the like, the viscosity of the photo-sensitive adhesive is reduced so as to facilitate a separation of the OLED substrate 3 from the evaporation carrier plate.

In an embodiment of the disclosure, the mounting chamber 102 for the viscosity reducing light source is sealed off at a side thereof facing towards the OLED substrate 3 by a glass plate or a quartz glass plate, such that the light ray emitted by the viscosity reducing light source 14 may pass therethrough and illuminate the photo-sensitive adhesive. The light mask plate 15 is provided on the second side surface of the carrier plate 1 facing towards the OLED substrate 3, and is configured to prevent the organic material finished on the OLED substrate 3 by evaporation from being subject to a qualitative change thereof during a process of irradiation onto the photo-sensitive adhesive by the viscosity reducing light source 14. During the evaporation, the viscosity reducing light source 14 does not emit light; while once the evaporation is completed, after the carrier plate 1 is transferred into the separation chamber, the viscosity reducing light source 14 is energized so as to decrease the viscosity of the photo-sensitive adhesive by the light emitted from the viscosity reducing light source 14. Certainly, it may be known to those skilled in the art that, the viscosity reducing light source 14 may for example be installed on an inner wall of the separation chamber. As such, once the evaporation carrier plate is flipped over, the OLED substrate 3 is located within a range of illumination by the viscosity reducing light source 14, and the light mask plate 15 is provided on the OLED substrate 3, and covers a location on the OLED substrate 3 which is covered with the organic material for manufacturing the OLED by the evaporation but without the photo-sensitive adhesive being applied thereon.

In still another embodiment of the disclosure, there is further provided an evaporation apparatus, comprising the evaporation carrier plate whose structural schematic view is illustrated as in FIG. 1.

There are at least one of numerous beneficial technical effects brought about by the technical solutions provided by the embodiments of the disclosure, as follows:

The embodiments of the disclosure may decrease the viscosity/stickiness of the sensitive adhesive 4 after the evaporation is completed by the viscosity reducing portion 2 of the evaporation carrier plate, so as to separate the OLED substrate 3 from the evaporation carrier plate, and to avoid an occurrence of deformation of the OLED substrate 3, or generation of fragments or debris from the OLED substrate, or even an overall breakup thereof, and in turn to avoid any adverse effect on both rhythm of production and product yield, when the evaporation carrier plate is separated from the OLED substrate 3 only by an external force.

Above numerical order of embodiments of the disclosure are only intended for depiction, rather than representing any ranking according to the advantages and disadvantages of these embodiments.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although the disclosure is described in view of the attached drawings, the embodiments disclosed in the drawings are only intended to illustrate the preferable embodiment of the present disclosure exemplarily, and should not be deemed as a restriction thereof.

Although several exemplary embodiments of the general concept of the present disclosure have been shown and described, it would be appreciated by those skilled in the art that various changes or modifications may be made in these embodiments without departing from the principles and spirit of the disclosure and lie within the scope of present application, which scope is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. An evaporation carrier plate, comprising:
a carrier plate; and
a viscosity reducing portion, which is provided on a first side surface of the carrier plate,
wherein an OLED substrate is secured on a second side surface opposite to the first side surface, of the carrier plate, by a sensitive adhesive, and the viscosity reducing portion is configured to operate so as to decrease viscosity of the sensitive adhesive following the evaporation.

2. The evaporation carrier plate according to claim 1, wherein the sensitive adhesive comprises one of a photo-sensitive adhesive and a heat-sensitive adhesive.

3. The evaporation carrier plate according to claim 2, wherein the sensitive adhesive is the heat-sensitive adhesive, and the viscosity reducing portion comprises a cooling pipe and a cryogenic fluid supply, the cooling pipe being provided on the carrier plate and positioned corresponding to a position on the carrier plate where the heat-sensitive adhesive is applied;
wherein the cryogenic fluid supply comprises a cryogenic fluid supply body, a first input port and a first output port, and the cooling pipe comprises a cooling pipe body, a second input port and a second output port; and
wherein the cryogenic fluid supply is configured to communicate with the second input port of the cooling pipe via the first output port thereof and to communicate with the second output port of the cooling pipe via the first input port thereof, following the evaporation; and is also configured to provide a cryogenic fluid to the cooling pipe.

4. The evaporation carrier plate according to claim 3, wherein the viscosity reducing portion further comprises a first check valve and a second check valve, the first check valve being provided between the first output port of the cryogenic fluid supply and the second input port of the cooling pipe and being configured to be switched on towards the second input port of the cooling pipe; while the second check valve being provided between the input port of the cryogenic fluid supply and the second output port of the cooling pipe, and being configured to be switched on towards the first input port of the cryogenic fluid supply.

5. The evaporation carrier plate according to claim 4, wherein the viscosity reducing portion further comprises a first flow regulating valve provided between the first check valve and the second input port of the cooling pipe, and a second flow regulating valve provided between the second output port of the cooling pipe and the second check valve.

6. The evaporation carrier plate according to claim 3, wherein the carrier plate is provided with a cavity therein, in which the cooling pipe is in turn provided.

7. The evaporation carrier plate according to claim 3, wherein a groove is provided on the first side surface of the carrier plate facing away from the OLED substrate, and positioned to be aligned with a position on the carrier plate where the heat-sensitive adhesive is applied, with the cooling pipe being installed within the groove.

8. The evaporation carrier plate according to claim 3, wherein the cryogenic fluid is one of cooling water, cryogenic ethanol and liquid nitrogen.

9. The evaporation carrier plate according to claim 3, wherein the evaporation carrier plate further comprises pin holes formed thereon and a pin device having a plurality of ejector pins, and
wherein the pin device is configured to push upwards the OLED substrate to rise by the plurality of ejector pins which penetrate through the pin holes respectively so as to project therethrough to eject the OLED substrate in case that viscosity of the sensitive adhesive is decreased.

10. The evaporation carrier plate according to claim 9,
wherein the pin device comprises:
a pin mounting portion, which is mounted onto the carrier plate and configured to be movable in an axial direction of the pin holes;
the plurality of ejector pins, each of which is fixed at one end thereof onto the pin mounting portion, and is inserted at the other end thereof into the pin holes respectively; and
an automatic control portion, which is connected with the pin mounting portion, and
wherein the automatic control portion is configured to control the pin mounting portion to move in the axial direction of the pin holes in case that viscosity of the sensitive adhesive is decreased, such that each of the plurality of ejector pins penetrates through the pin holes respectively to project therethrough so as to push upwards the OLED substrate to rise.

11. The evaporation carrier plate according to claim 10, wherein each of the plurality of ejector pins are provided with a first deep hole and a second deep hole in an axial direction thereof in communication with the first deep hole, both of which are in communication with the cryogenic fluid supply respectively.

12. The evaporation carrier plate according to claim 11, wherein a cross section of a position where the first deep hole and the second deep hole of each of the plurality of ejector pins communicate with each other is larger than a cross section of either one of the first deep hole and the second deep hole.

13. The evaporation carrier plate according to claim 3, wherein the cooling pipe is secured to the carrier plate by one of welding or snap-fit.

14. The evaporation carrier plate according to claim 3, wherein a material of the cooling pipe comprises one of copper, silver, aluminum, molybdenum and tungsten.

15. The evaporation carrier plate according to claim 2, wherein the sensitive adhesive is the photo-sensitive adhesive, and the viscosity reducing portion comprises a viscosity reducing light source and a light mask plate,
wherein the carrier plate is provided therein with a mounting chamber for the viscosity reducing light source in which the viscosity reducing light source is in turn mounted, a position on the carrier plate where the photo-sensitive adhesive is applied being within a range of illumination by the viscosity reducing light source, and
wherein the light mask plate is provided on the second side surface of the carrier plate facing towards the OLED substrate, and is configured to shield a location on the OLED substrate which is covered with an organic material for manufacturing the OLED by the evaporation but without the photo-sensitive adhesive being applied thereon.

16. The evaporation carrier plate according to claim 15, wherein the viscosity reducing light source is an ultraviolet light source.

17. An evaporation apparatus, comprising the evaporation carrier plate according to claim 1.
